(19) United States
(12) Patent Application Publication
(10) Pub. No.: US 2016/0027866 A1
(43) Pub. Date: Jan. 28, 2016

(54) SEMICONDUCTOR DEVICE

(71) Applicant: Fuji Electric Co., Ltd., Kanagawa (JP)

(72) Inventor: Koh YOSHIKAWA, Nagano (JP)

(73) Assignee: Fuji Electric Co., Ltd., Kanagawa (JP)

(21) Appl. No.: 14/792,788

(22) Filed: Jul. 7, 2015

(30) Foreign Application Priority Data
Jul. 22, 2014 (JP) 2014-148848

(51) Int. Cl. H01L 29/06; H01L 29/40; H01L 29/872

(52) U.S. Cl. CPC H01L 29/063; H01L 29/872; H01L 29/0619; H01L 29/404; H01L 29/0649

(57) ABSTRACT

A semiconductor device, including: a semiconductor substrate of a first conductivity type, the semiconductor substrate having an edge termination area adjacent to an outermost periphery thereof; an anode structure provided in a bottom surface of the semiconductor substrate; a cathode region of the first conductivity type selectively provided in a top surface of the semiconductor substrate at an inner side of the edge termination area; a cathode electrode on the cathode layer; and an isolation region of a second conductivity type in the outermost periphery of the semiconductor substrate, the isolation region having a vertically elongated shape such that a bottom of the isolation region is connected to an outermost periphery of the anode structure on the bottom surface of the semiconductor substrate and a top of the isolation region reaches the top surface of the semiconductor substrate.

### BACKGROUND OF THE INVENTION

1. Technical Field

The present invention relates to a new structure for improving the reverse recovery resistance of diodes.

2. Background Art

In recent years, power semiconductor devices have achieved lower loss, higher switching speed, lower inductance in peripheral circuits, a snubberless system, and other features. As a result, there is greater demand for improvement in the reverse recovery properties of diodes (freewheeling diodes: FWD) that are used in combination with power semiconductor devices. Desired improvements include greater reverse recovery resistance, lower reverse recovery loss, and use of soft switching. In particular, expectations on the maximum rate of change in reverse recovery current, di/dt, have been on a rise over the years; improvement in the maximum rate of change in reverse recovery current, di/dt, or reverse recovery resistance, is therefore crucial.

FIG. 16 is a cross-sectional view of primary parts of a basic PIN diode 100 from an outer periphery of an active region 105 to an edge termination area 104. A p-type anode region 102 is selectively formed at a center of one principal surface of an n-type semiconductor substrate 101. An n-type cathode layer 103 and a cathode electrode 106 are formed on the other principal surface over the entire surface. An anode electrode 107 contacts a surface of the p-type anode region 102. At the same time, an edge termination area 104 is provided in a periphery surrounding the p-type anode region 102. The edge termination area 104 includes electric field mitigating structures such as field-limiting rings (FLRs 108), constituted by p-type regions, and field plates (FPs 109). The semiconductor substrate is cut off at the outermost periphery of the edge termination area 104.

When the silicon diode 100 is forward biased (with the p-type anode region 102 as the positive side and the n-type cathode layer 103 as the negative side) and the voltage applied to the p-n junction at the boundary of the p-type anode region 102 and the n-type semiconductor substrate 101 (n⁻ drift layer) exceeds the built-in voltage at approximately 0.6V or above, holes are injected into the n⁻ drift layer and electrons are injected from the high-concentration n-type cathode layer 103 to achieve charge neutrality. As a result, the semiconductor substrate 101 undergoes conductivity modulation and manifests a current-voltage characteristic in which current surges exponentially in accordance with the amount of holes injected (in other words, in accordance with the rise of positive voltage). In the diode 100 (FIG. 16), the p-type anode region 102 and the anode electrode 107 are normally formed in a central portion of one principal surface of the n-type semiconductor substrate 101 that excludes the edge termination area 104 in the periphery. The cathode layer 103 and the cathode electrode 106, on the other hand, are formed on the opposite surface of the substrate over the entire surface. For this reason, a large number of the injected holes are found below the edge termination area 104 inside the substrate.

In a bipolar device such as the diode 100 shown in FIG. 16, a reverse recovery process is required when a forward bias transitions to a reverse bias. This reverse recovery process refers to a process in which the minority carriers (holes) injected into the n− drift layer when a forward bias is applied to the diode are removed to the anode electrode or disappear by recombining with electrons when the forward bias transitions to a reverse bias. In the reverse recovery process, a short circuit, or a state in which current flows, occurs briefly even though a reverse bias, or reverse voltage, is blocked. This short-circuit current is called a reverse recovery current. It is known that the higher the frequency of the reverse recovery current becomes, the steeper the di/dt and the larger the peak current, raising the risk of causing element destruction. Once the reverse recovery current peaks off, a depletion layer expands from the p-n junction and a normal reverse-blocking state is achieved.

This phenomenon, in which the element is destroyed during reverse recovery, is more likely to occur near the boundary between the active region 105 and the edge termination area 104. The destruction occurs due to a thermal destruction caused by concentrations of electric field and current at the boundary. The concentration of electric field occurs due to a high electric field at cylindrical (four side faces) or spherical (four corners) p-n junctions 110 at the outer periphery of the anode region 102. The concentration of current occurs when the hole carriers that remain below the edge termination area 104 regardless of the electric field mitigating structures concentrate at a side face 110 of the outer periphery of the anode region to pass through to the anode electrode 107 (negative electrode) in reverse recovery.

A known structure of a conventional diode that suppresses the aforementioned concentration of current is a structure in which the outermost periphery of the anode electrode, which contacts the front surface of the anode region, is pushed back toward the central side so that the outer periphery of the anode region not contacting the anode electrode functions as a resistance region against a reverse recovery current flowing in a horizontal direction (Patent Document 1). In another known structure (Patent Document 2), a region with a short carrier lifetime is provided near the p-n junction between the anode-region and the edge termination area, where electric field is more likely to concentrate, so as to suppress hole carriers from being injected into the region with a high concentration of electric field (Patent Document 2). Also known is a structure in which an insulating groove that is almost as deep as, or deeper than, the anode region is formed near the outer periphery of the anode region, so that a concentration of electric current can be suppressed by receding the electrode by a narrower width than in Patent Document 1 (Patent Document 3). Another disclosed structure is a diode having a p-type anode layer on a reverse surface side, an n-type cathode region on a front surface side, and a p-type isolation region disposed such that one end is connected to the p-type anode layer on the reverse surface and the other end reaches the front surface side via the substrate side face (Patent Document 4). Also disclosed is a reverse-blocking IGBT that is equipped with a p-type isolation region extending from a reverse surface side to a front surface side and that has electric field mitigating structures such as guard rings and field plates in the edge termination area (Patent Document 5).

### RELATED ART DOCUMENTS

### Patent Documents

Patent Document 1: Japanese Patent Application Laid-Open Publication No. H9-232597 (Abstract; FIG. 1)

Patent Document 2: Japanese Patent Application Laid-Open Publication No. 2001-135831 (Abstract; FIG. 1)

Patent Document 3: Patent Document 3: Japanese Patent Application Laid-Open Publication No. 2000-340806 (Abstract; FIG. 1)

Patent Document 4: Japanese Patent Application Laid-Open Publication No. H8-172205 (FIG. 2)

Patent Document 5: Japanese Patent Application Laid-Open Publication No. 2011-77202 (FIG. 1)

### SUMMARY OF THE INVENTION

The methods of suppressing reverse recovery current described above, however, go as far as mitigating the concentration of current at regions where electric field concentrates, and can only improve the reverse recovery resistance to a limited extent. The present invention aims to provide a semiconductor device capable of improving reverse recovery resistance without being constrained by the limitations of conventional methods for improving reverse recovery resistance. Another objective of the present invention is to provide a semiconductor device capable of making a high breakdown voltage easier to obtain and reducing switching loss.

Additional or separate features and advantages of the invention will be set forth in the descriptions that follow and in part will be apparent from the description, or may be learned by practice of the invention. The objectives and other advantages of the invention will be realized and attained by the structure particularly pointed out in the written description and claims thereof as well as the appended drawings.

To achieve these and other advantages and in accordance with the purpose of the present invention, as embodied and broadly described, in one aspect, the present disclosure provides a semiconductor substrate of a first conductivity type, the semiconductor substrate having an edge termination area adjacent to an outermost periphery thereof; an anode structure provided in a bottom surface of the semiconductor substrate; a cathode region of the first conductivity type selectively provided in a top surface of the semiconductor substrate at an inner side of the edge termination area; a cathode electrode on the cathode layer; and an isolation region of a second conductivity type in the outermost periphery of the semiconductor substrate, the isolation region having a vertically elongated shape such that a bottom of the isolation region is connected to an outermost periphery of the anode structure on the bottom surface of the semiconductor substrate and a top of the isolation region reaches the top surface of the semiconductor substrate.

It is preferable that the cathode electrode cover, via an insulating film, an outer surface portion of the cathode region and extend so as to cover, via the same insulating film, a portion outside the cathode region.

It is preferable that the anode structure include an anode layer of the second conductivity type provided in the bottom surface of the semiconductor substrate and an anode electrode forming an ohmic contact on the anode layer.

It is preferable that the anode structure include an anode electrode forming a Schottky contact with the bottom surface of the semiconductor substrate of the first conductivity type.

It is preferable that the edge termination area of the semiconductor substrate have an electric field mitigating structure that includes: a plurality of field-limiting rings of the second conductivity type provided in the top surface of the semiconductor substrate; and metal field plates respectively in contact with the field-limiting rings.

It is preferable that gaps between the plurality of field-limiting rings of the second conductivity type gradually widen from the isolation region toward the cathode region.

It is preferable that the electric field mitigating structure have a reduced surface field (RESURF) region of the second conductivity type contacting the isolation region on the bottom surface of the semiconductor substrate.

It is preferable that the electric field mitigating structure further include a ring-shaped buffer region of the first conductivity type in a periphery of the cathode region, the ring-shaped buffer region having a lower concentration of impurities than the cathode region.

It is preferable that the ring-shaped buffer region of the first conductivity type contact a peripheral side of the cathode region.

It is preferable that the ring-shaped buffer region of the first conductivity type be provided so as to be spaced apart from a peripheral side of the cathode region.

It is preferable that the ring-shaped buffer region of the first conductivity type be electrically connected to an electrode that is set at a floating potential.

It is preferable that the ring-shaped buffer region of the first conductivity type be formed in a plurality.

According to at least one aspect of the present invention, it is possible to provide a semiconductor device capable of improving reverse recovery resistance without being constrained by the limitations of conventional methods for improving reverse recovery resistance. At the same time, it is possible to provide a semiconductor device capable of making a high breakdown voltage easier to obtain and reducing switching loss.

It is to be understood that both the foregoing general description and the following detailed description are exemplary and explanatory, and are intended to provide further explanation of the invention as claimed.

### BRIEF DESCRIPTION OF THE DRAWINGS

FIG. 1 is a cross-sectional view of primary parts of a diode according to Embodiments 1 and 2 of the present invention.

FIGS. 2A to 2C show cross-sectional views of primary parts of the diode according to Embodiment 1 of the present invention that is used in a simulation to identify a portion where electric field is high and a portion where current concentrates. FIG. 2A shows a cross-sectional view of primary parts of the diode according to Embodiment 1, and FIGS. 2B and 2C respectively show portions with the highest electric field strength (high electric field) and a high concentration of current.

FIGS. 3A to 3C show cross-sectional views of a conventional diode used in a simulation to identify a portion where electric field is high and a portion where current concentrates. FIG. 3A shows a cross-sectional view of primary parts of a diode having a conventional structure, and FIGS. 3B and 3C respectively show portions with the highest electric field strength (high electric field) and a high concentration of current.

FIG. 4 is a diagram showing respective breakdown voltage waveforms of the diodes according to Embodiment 1 and 2 and the conventional diode that were used in the simulation.

FIG. 5 is a cross-sectional view of primary parts of a diode according to Embodiment 3 of the present invention.

FIG. 6 is a cross-sectional view of primary parts of a diode according to Embodiment 4 of the present invention.

FIG. 7 is a cross-sectional view of primary parts of a diode according to Embodiment 5 of the present invention.

FIG. 8 is a cross-sectional view of primary parts of a diode according to Embodiment 6 of the present invention.

FIG. 9 is a cross-sectional view of primary parts of a diode according to Embodiment 7 of the present invention.

FIG. 10 is a cross-sectional view of primary parts of a diode according to Embodiment 8 of the present invention.

FIG. 11 shows a distribution of electric field strength of the diode according to Embodiment 8 of the present invention.

FIG. 12 is a cross-sectional view of primary parts of a diode according to Embodiment 9 of the present invention.

FIG. 13 is a distribution of electric field strength of the diode according to Embodiment 9 of the present invention.

FIG. 14 is a cross-sectional view of primary parts of a diode according to Embodiment 10 of the present invention.

FIG. 15 a distribution of electric field strength of the diode according to Embodiment 10 of the present invention

FIG. 16 is a cross-sectional view of primary parts of a conventional diode.

### DETAILED DESCRIPTION OF EMBODIMENTS

Below, working examples of a semiconductor device according to the present invention will be described in detail with reference to diagrams. In this specification and attached diagrams, regions beginning with “n” or “p” respectively indicate that such regions contain a large number of electrons and hole carriers. In addition, “+” and “−” signs attached to the “n” and “p” respectively indicate that the concentration of impurity is higher or lower relative to each other. Note that in the following descriptions and attached diagrams of the working examples, identical reference characters are given to identical configurations, and overlapping descriptions will be omitted. In addition, the attached diagrams, which will be described in the working examples, are not illustrated with accurate scales or dimensional ratios, so that the diagrams are easier to understand. The present invention is not limited by the descriptions of the following working examples, and may be modified without departing from the spirit thereof.

### Working Example 1

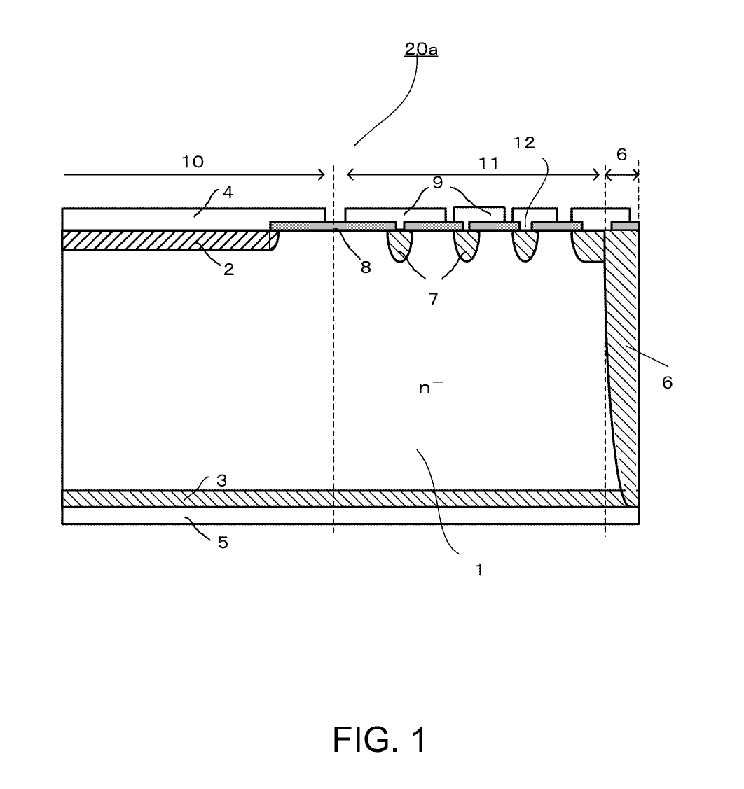

A structure of a diode 20a of Embodiment 1 of a semiconductor device according to one aspect of the present invention will be described in detail with reference to FIG. 1. An n-type semiconductor substrate 1, which is made of a silicon semiconductor, has a resistivity of approximately 28 Ωcm and a thickness of approximately 70 μm. When configured as a diode, the n-type semiconductor substrate 1 functions as an n⁻ drift layer. The diode 20a is schematically configured by the following primary parts, which are shown as a cross-sectional view in FIG. 1: an active region 10, which is configured at a center of a principal surface of the n-type semiconductor substrate 1 (only a portion of the outer peripheral portion thereof is shown in FIG. 1); an edge termination area 11 surrounding the outer side of the active region 10; and a p-type isolation region 6, which connects the principal surfaces of the semiconductor substrate 1 along the cross section on the outer side of the edge termination area 11.

On one principal surface (surface on the top side of FIG. 1) of the active region 10, an n-type cathode region 2 with a surface concentration of approximately 1×10¹⁹ cm⁻³ and a diffusion depth of approximately 3 μm is selectively formed at a center of the semiconductor substrate 1. On a surface of the n-type cathode region 2, a cathode electrode 4, which is made of a metal film having aluminum, nickel, or the like as the main component, forms an ohmic contact. Note, however, that at an outer periphery of the n-type cathode region 2, the cathode electrode 4 is stacked onto the surface thereof with an insulating film 8 therebetween and is extended approximately 10 μm to an outer side of the n-type cathode region 2 while sandwiching the insulating film with the n-type cathode region 2. Additionally, on the other surface of the n-type semiconductor substrate 1, a p-type anode layer 3 with a surface concentration of approximately 1×10¹⁷ cm⁻³ and a diffusion depth of approximately 0.5 μm is formed across the entire surface. An anode electrode 5, which is made of a metal film formed by a sputtering deposition or the like, contacts a surface of the p-type anode layer 3.

On a surface of the edge termination area 11, field-limiting rings (hereinafter FLRs 7) constituted by p-type regions are formed so as to spaced apart from one another and surround the outer periphery of the n-type cathode region 2. The surface of the edge termination area 11 is covered by the insulating film 8 except for openings 12 provided in the surfaces of the FLRs 7. Additionally, conductive field plates (FPs 9) are provided so as to contact the surfaces of the FLRs 7 via the openings 12 of the insulating film 8 and cover the surfaces between the FLRs 7 via the insulating film. The FLRs 7 are p-type regions, and it is preferable that the FLRs 7 have a surface concentration of approximately 5×10¹⁸ cm⁻³ and a depth diffusion of approximately 7 μm. In addition, it is preferable that a plurality of FLRs 7 be provided with gaps between one another and in such a manner that the gaps increase from the outer peripheral side toward the inner peripheral side of the semiconductor substrate of the diode 20a.

The p-type isolation region 6 formed as a p-type region is found at an outermost periphery of the semiconductor substrate of the diode 20a, and is formed so as to surround the edge termination area 11. One end of the p-type isolation region 6 is connected to the p-type anode layer 3 on the side of one principal surface, while the other end extends along a side face of the substrate and reaches the other principal surface.

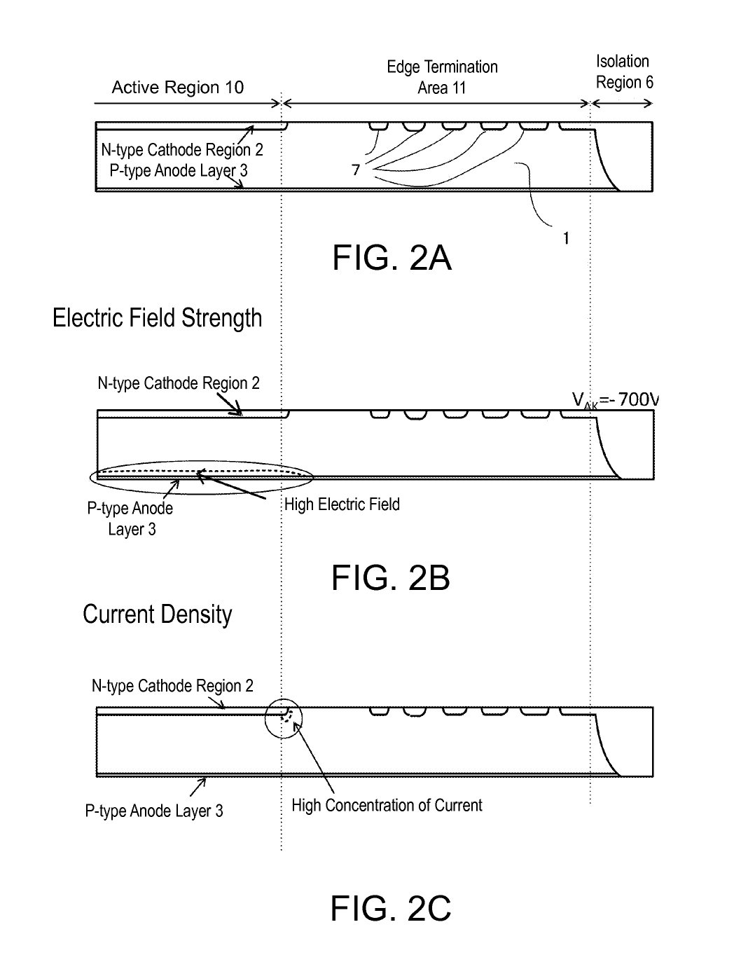

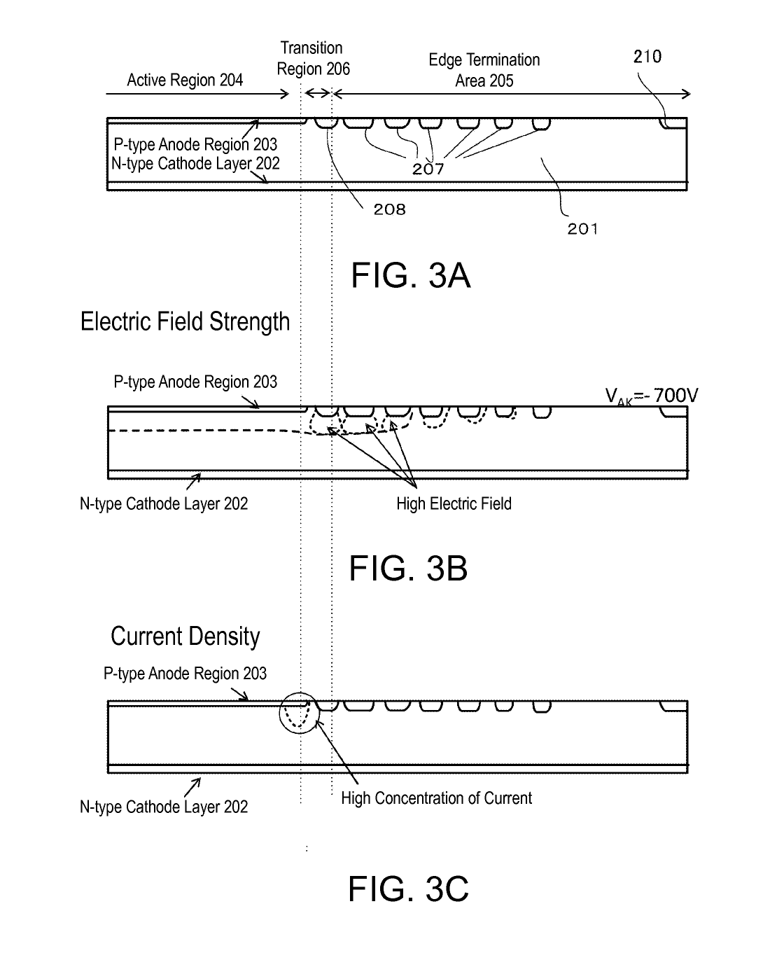

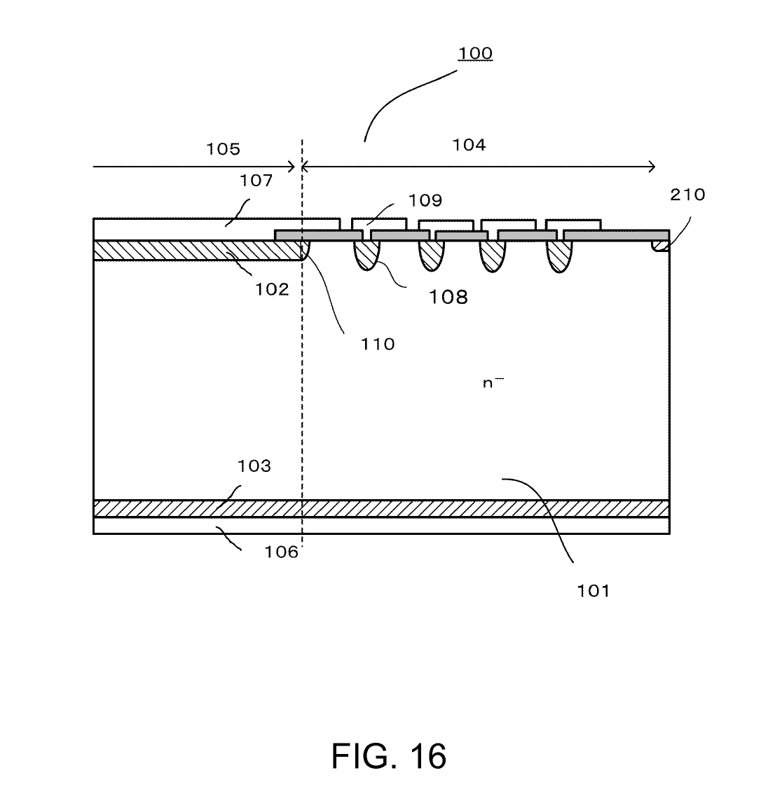

FIG. 2A shows a cross-sectional view of primary parts of a diode according to Embodiment 1. Using a diode comparable to the diode according to Embodiment 1, device simulation was conducted to investigate the distribution of electric field strength of the diode when a reverse voltage is applied and the distribution of current density when a forward voltage is applied. FIGS. 2B and 2C respectively show portions where the highest electric field strength (high electric field) and a high concentration of current were observed from the results. As a comparison, the same method was used to investigate the distribution of electric field strength and the distribution of current density of a conventional diode structure shown in FIG. 3A (a structure similar to the conventional diode shown in FIG. 16). FIGS. 3B and 3C respectively show portions where the highest electric field strength (high electric field) and a high concentration of current were observed from the results. Semiconductor substrates 1 and 201 in FIGS. 2A to 2C and FIGS. 3A to 3C have a resistivity of approximately 28 Ωcm and a thickness of 70 μm. In addition, the design breakdown voltage and the current conditions of anode layers 3 and 203 and n-type cathode regions 2 and 202 were set to be as close to each other as possible.

In the conventional diode shown in FIGS. 3A to 3C, a transition region 206 with a width of approximately 20 μm is provided (based on Patent Document 1) so that current and electric field do not concentrate at the same portion in an active region 204 or an edge termination area 205. At the same time, a p-type region 208 is provided at an end of the transition region 206 so that a higher breakdown voltage is easier to obtain. The p-type region 208 is larger than the radius of curvature of the outer cross section of the anode region 203 and is covered by an extended portion of an anode electrode via an insulating film.

When a reverse voltage is applied to the diodes in FIGS. 2A to 2C and FIGS. 3A to 3C, a strong electric field strength (high electric field) is found on the side of the main junction (junction at the anode layer 3 or the anode region 203), as shown in FIGS. 2B and 3B. As a result, a high electric field is found on different principal surfaces in the diodes of FIGS. 2A to 2C and FIGS. 3A to 3C. Specifically, while the diode of the working example (FIGS. 2A to 2C) has the highest electric field strength on the flat main junction surface, the conventional diode (FIGS. 3A to 3C) has higher electric field strengths at the curvatures of the p-type region 208 in the transition region 206 and the FLRs 207 than on the main junction surface. As a result, due to the concentration of electric field, the diode in FIGS. 3A to 3C reaches the critical field of silicon in the p-type region 208 or the FLRs 207 at a lower voltage than the design breakdown voltage, and is therefore more likely to break down. It follows that the diode of the working example (FIGS. 2A to 2C) is more likely to obtain a high breakdown voltage (design breakdown voltage) than the conventional diode (FIGS. 3A to 3C) when a semiconductor substrate with an identical resistivity and an identical thickness is used.

In addition, when a reverse voltage is applied to the diode according to the working example shown in FIGS. 2A to 2C, the space charge region (depletion layer) expands from the main junction and the p-type isolation region 6 toward the edge termination area. The diode according to the working example is therefore structured such that the space charge region expands more easily from the main junction to the edge termination area 11, and electric field is less likely to increase than in the conventional diode (FIGS. 3A to 3C). For this reason, even if an edge termination region is short (has a narrow width), the electric field can be kept lower than in vicinity of the main junction. Specifically, as shown in FIGS. 2A and 3A, the diode of the working example (FIGS. 2A to 2C) has five FLRs 7 while the conventional diode (FIGS. 3A to 3C) has six FLRs 207. Therefore, a high breakdown voltage is more easily obtained in the diode of the working example despite the narrower surface length (width) of the edge termination area. The reason for this is that, as mentioned above, the diode according to at least one aspect of the present invention shown in FIGS. 2A to 2C has the highest electric field near the main junction of the anode layer 3, which is a flat, large area, while the conventional example reaches a high electric field (the critical field of Si) faster at a lower breakdown voltage in narrow, localized regions near the FLRs 207 and breaks down.

FIGS. 2C and 3C show portions with high current density (portions with high current concentration) in reverse recovery. As shown, current concentrates on a surface where the edge termination area is found on a side of the active region at an outer periphery of either the anode region or the cathode region (near an electrode contacting portion). In the diode of the working example (FIGS. 2A to 2C), current and electric field respectively concentrate on separate surfaces of the substrate, as shown in FIG. 2C. (In the diode of the working example (FIGS. 2A to 2C), electric field does not increase to the extent that the breakdown voltage falls below the design voltage even at the main junction where electric field is high.) In the conventional diode (FIGS. 3A to 3C), in contrast, electric field and current concentrate in regions close to each other on the same surface of the substrate. As a result, in the diode of the working example, where electric field and current concentrate in separate regions, it is possible to obtain a high reverse recovery resistance and reduce switching loss.

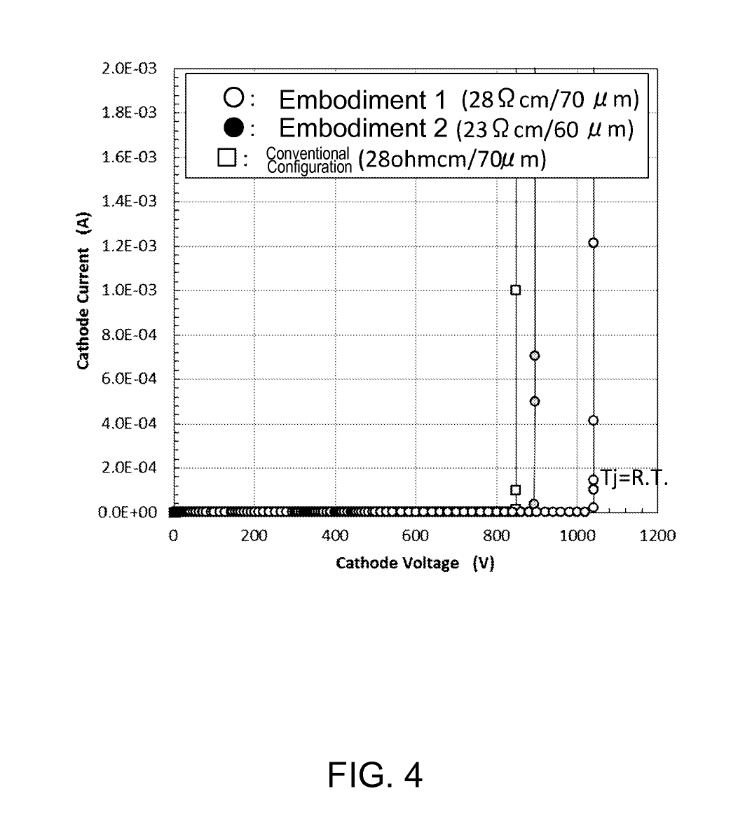

A diode according to Embodiment 2 (not illustrated) will be described. This diode differs from the diode 20a according to Embodiment 1 in that the resistivity of the semiconductor substrate 1 is changed from approximately 28 Ωcm to 23 Ωcm, and the thickness thereof is changed from 70 μm to 60 μm. All other conditions are identical to those of the diode 20a. FIG. 4 shows respective breakdown voltage waveforms of the diodes according to Embodiments 1 and 2 and the conventional diode (FIGS. 3A to 3C). As clearly evident in FIG. 4, the diode according to Embodiment 1 is able to achieve a higher breakdown voltage than the conventional diode due the reasons described above, even when the conditions of the semiconductor substrate 1 are identical. The diode according to Embodiment 2 is able to obtain a breakdown voltage comparable to that of the conventional diode, even with a semiconductor substrate 1 that is thinner (reduced from 70 μm to 60 μm) than those of Embodiment 1 (FIG. 1) and the conventional diode (FIGS. 3A to 3C). Thus, the diode according to Embodiment 2 is able to obtain a lower forward voltage and a lower reverse recovery loss (switching loss), and is therefore advantageous.

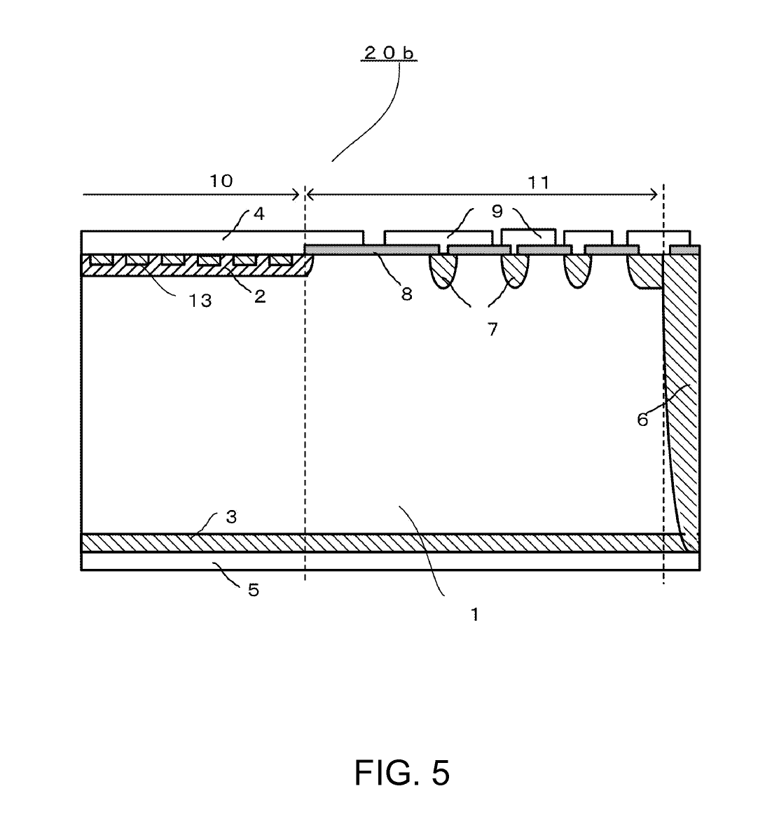

FIG. 5 shows a diode 20b according to Embodiment 3, which is a modification example of the diode 20a according to Embodiment 1. A plurality of p-type layers 13 may be selectively formed on a surface layer of an n-type cathode region 2, so that the depletion layer is less likely to reach a cathode electrode 4 in reverse bias.

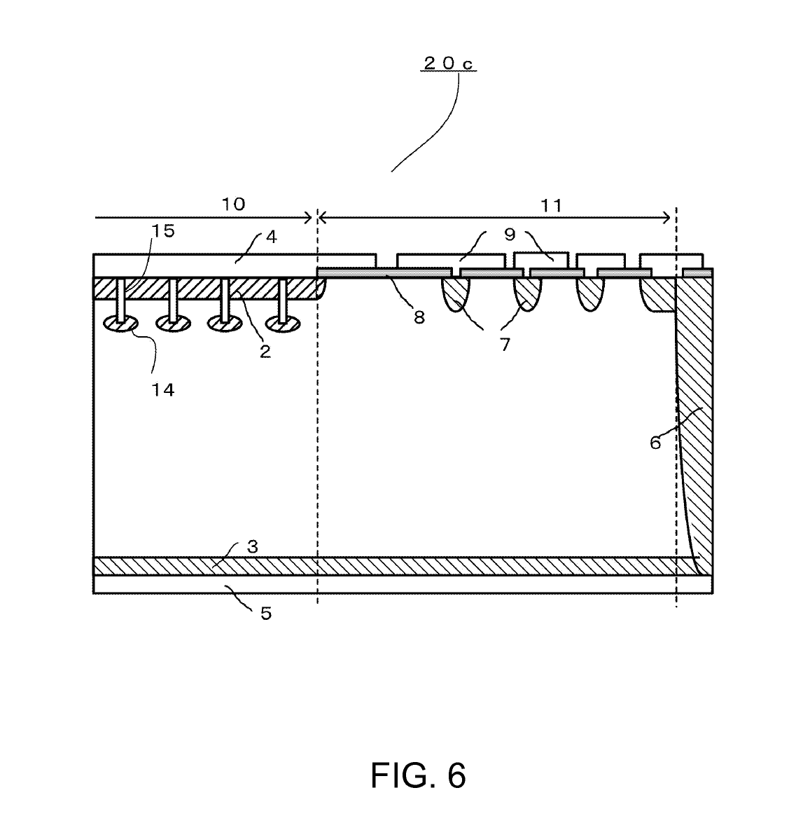

FIG. 6 shows a diode 20c according to Embodiment 4. In this modification example of the diode 20a according to Embodiment 1 shown in FIG. 1, a plurality of trenches 15 are selectively formed in a surface layer of an n-type cathode region 2. In addition, an anode electrode 4 is embedded in the trenches 15, and a high-concentration n-type layer 14 is formed at each distal end (bottom) of the trenches 15.

In the diodes 20b and 20c according to Embodiments 3 and 4, a primary diffusion region 10 of an active region 10, deep and complex diffusions of an edge termination area 11, and the like are formed on a surface on the cathode side. For this reason, these diodes are suitable and advantageous for designing diodes requiring structures with complex and difficult formation processes on the cathode side (such as patterning processes and adjustments to increase the diffusion depth).

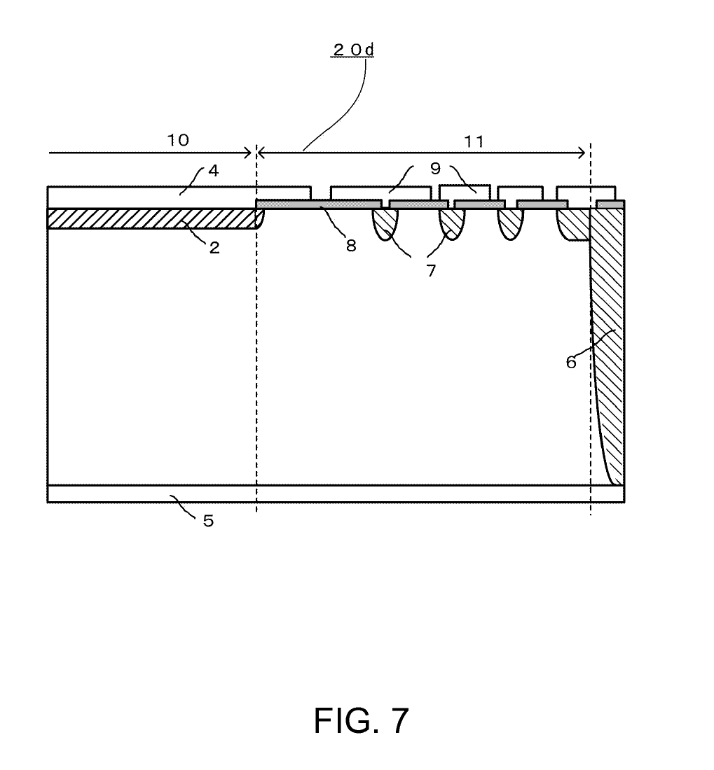

FIG. 7 shows a diode 20d according to Embodiment 5, a modification of the diode 20a according to Embodiment 1 shown in FIG. 1. The diode 20d differs from the diodes according to Embodiments 1 to 4 described above in that the diode 20d does not have a p-type anode layer 3, and an n-type semiconductor substrate 1 and an anode electrode 5 are formed into a Schottky barrier junction.

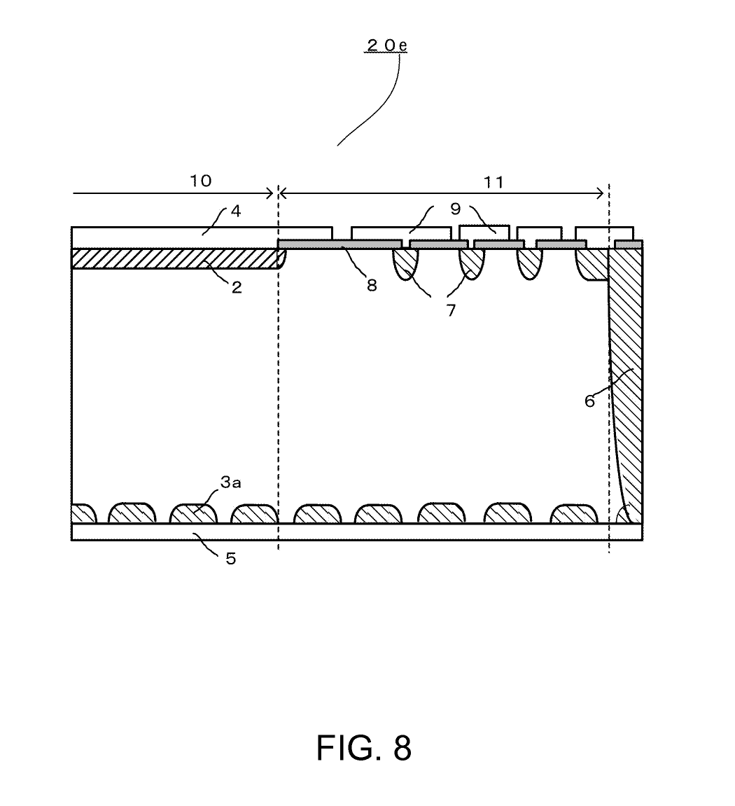

FIG. 8 shows a diode 20e according to Embodiment 6. This diode is also a modification of the diode 20a according to Embodiment 1 shown in FIG. 1. The diode 20e differs from the diodes described above in that a plurality of p-type anode layers 3a are selectively formed on a surface of an n-type semiconductor substrate 1, and the n-type semiconductor substrate 1 and an anode electrode 5 are formed into a merged pin Schottky (MPS) diode structure.

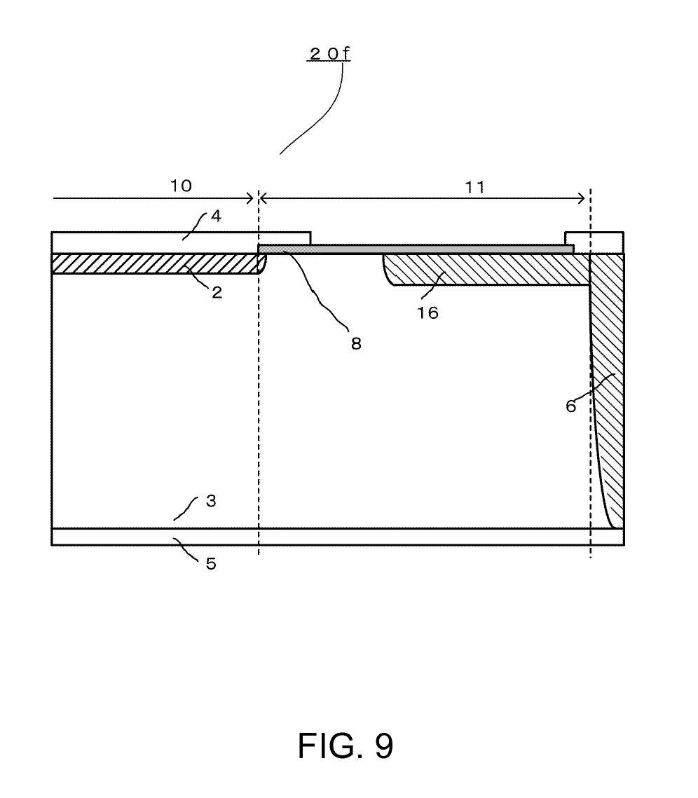

FIG. 9 shows a diode 20f according to Embodiment 7. This diode differs from the diodes according to Embodiments 1 to 6 described above in that the electric field mitigating structure of the edge termination area 11, which includes a combination of the FLRs 7 and the FPs 9, is replaced by a graded mitigating structure formed by a Junction Termination Extension (JTE 16). In the diode 20f according to Embodiment 7, unlike in the conventional diode (FIGS. 3A to 3C), a space charge region (depletion layer) extends from a surface of an isolation region 6 on the front surface side. For this reason, the electric field mitigating structure, made of an LTE 16 constituted by a low-concentration p-type region, is formed on the side of the isolation region away from, and not close to, the active region.

Thus, in the diodes according to Embodiments 1 to 7 described above, a high concentration of current is found on the principal surface on the side of the cathode region 2, while a high electric field strength is found near the main junction on the side of the p-type anode layer, regardless of the shape or the structure of the p-type anode layer 3a. As a result, a high reverse recovery resistance can be achieved. In addition, since electric field does not concentrate in a narrow, localized region, these diodes are able to achieve a high breakdown voltage and low switching loss.

In addition, in the diodes according to Embodiments 1 to 7 of the present invention, the space charge region (depletion layer) that expands from the p-type isolation region 6 to the active region 10 in reverse bias expands by a larger distance per unit voltage of increase in applied reverse voltage, and therefore expands easily. The reason is that in the edge termination area 11, the depletion layer expands from three directions: the p-type anode electrode 5 on the reverse surface, the p-type isolation region 6, and the FLRs 7 on the front surface. As the depletion layer expands, charges from the drift layer supplied to the depletion layer decrease, making it necessary for the depletion layer to expand further. When a reverse-biased p-n junction is formed between a p-collector region and an n− drift region in a reverse-blocking IGBT, as is the case in Patent Document 5, leakage current surges as the depletion layer widens within the n− drift region and approaches the p-base region on the front surface side. For this reason, it is necessary to set the thickness of the n− drift region such that an end of the depletion layer and the p-base region are kept apart by a few dozen to a few hundred μm even when the reverse voltage is increased to the design breakdown voltage.

In contrast, the diode according to at least one aspect of the present invention shown in FIG. 1 is equipped with the n-type cathode region 2 instead of a p-base region on the front surface side, unlike the structure in which the reverse-biased p-n junction built into the reverse-blocking IGBT. For this reason, even if the depletion layer (expanding from the p-type isolation region 6) reaches the n-type cathode region 2, the expansion speed of the depletion layer inside the n-type cathode region 2 is very slow due to the high concentration, as mentioned above. As a result, there is an extremely small chance that the depletion layer will reach the cathode electrode, and therefore the leakage current will not increase. In other words, even if the depletion layer (expanding from the p-type isolation region 6) reaches and enters the n-type cathode region 2 from an outer periphery and proceeds toward the cathode electrode 4 along the principal surface, no problems will arise unless the depletion layer reaches the cathode electrode 4.

In the diode according to at least one aspect of the present invention, there is no need to provide a gap between the end of the depletion layer and the p-base region, which is necessary when the depletion layer expands from the reverse-biased p-n junction in the reverse-blocking IGBT. It is therefore possible to substantially reduce the area of the edge termination area 11 (the length (width) of the edge termination area 11). However, if the depletion layer that has entered the n-type cathode region 2 reaches the cathode electrode 4, a very small number of holes flow out, resulting in a surge of leakage current. For this reason, it is necessary to set the concentration and the diffusion depth of the n-type cathode region 2 of the diode according to at least one aspect of the present invention such that the end of the depletion layer is prevented from reaching the cathode electrode 4.

Additionally, it is preferable that the outer peripheral end of the n-type cathode region 2 be separated from the outer peripheral end of the cathode electrode 4, which otherwise contacts the n-type cathode region 2, by approximately 0.3 to 10 μm. The distance by which the depletion layer penetrates the n-type cathode region 2 when an avalanche current flows into the diode is equal to the distance at which the integrated value of concentration from the outer peripheral end of the n-type cathode region to the front end of the depletion layer becomes 1.3×10¹²/cm². This distance is equivalent to the value obtained by multiplying the critical field strength of silicon, E_{c}, by the permittivity of silicon, ε, and dividing the product by the elementary charge, q. The strength of the critical field of silicon E_{c} is approximately 2.0×10⁵V/cm, although the value depends on the doping concentration of the semiconductor. It is preferable that the surface concentration of the n-type cathode region 2 be at least 1×10¹⁹/cm³. At the same time, it is preferable that the n-type cathode region 2 be joined to the cathode electrode 4 by an ohmic contact and that the resistance of contact with the cathode electrode 4 be made sufficiently small.

As a result, the depletion layer in the active region 10 expands from the p-type anode layer 3 toward the cathode region 2 in a direction perpendicular to the substrate 1 and penetrates the n-type cathode region 2. The depletion layer then stops immediately before the cathode electrode 4 (approximately 0.1 to 0.3 μm) without reaching the cathode electrode 4. However, electric charge at an outer peripheral end of the n-type cathode region 2 is less in the direction along the principal surface than in the depth direction. For this reason, there is greater risk that the depletion layer that has penetrated along the front surface of the substrate reaches the cathode electrode 4. Therefore, the surface of the outer peripheral end of the cathode region 2 is separated from the outer peripheral end of the cathode electrode 4, which otherwise contacts the n-type cathode region 2. This separating distance is set longer than 0.3 μm, which is the depth of the front end of the depletion layer, which has penetrated the active region 10 perpendicular to the active region 10, from the front surface. As a result, the front end of the depletion layer penetrating the n-type cathode region 2 from the outer peripheral end thereof along the front surface does not reach the cathode electrode 4 and is separated by a distance. Setting this separating distance to approximately 10 μm, for example, ensures that the front end of the depletion layer is prevented from reaching the cathode electrode 4.

### Working Example 2

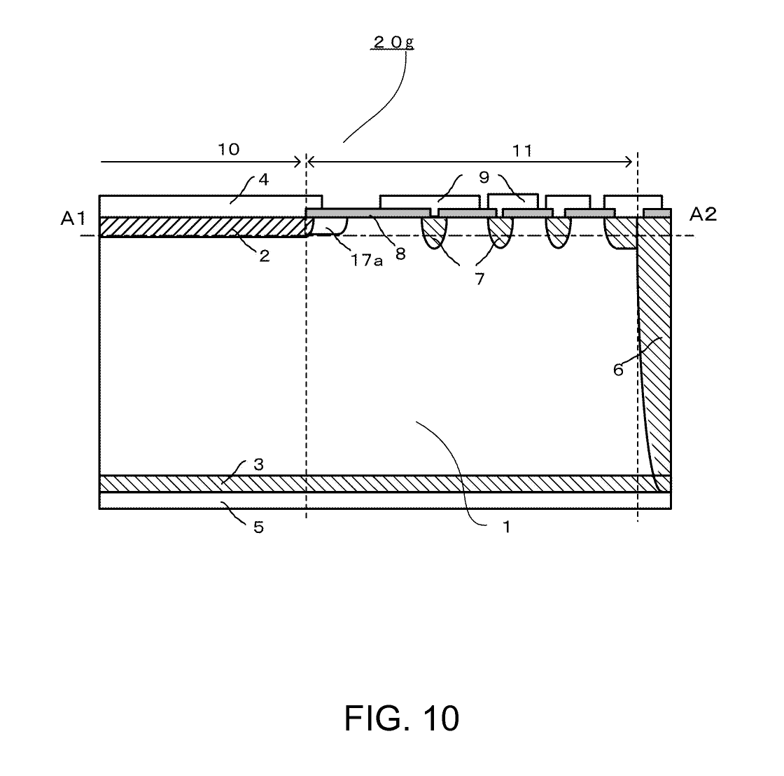

A structure of a diode 20g of Embodiment 8 of a semiconductor device according to one aspect of the present invention will be described with reference to a cross-sectional view of the primary parts in FIG. 10. An n-type semiconductor substrate 1, which constitutes the semiconductor substrate, has a resistivity of approximately 28 Ωcm and a thickness of approximately 70 μm. When configured as a diode, the n-type semiconductor substrate 1 functions as an n⁻ drift layer. On one surface (front surface) of the n-type semiconductor substrate 1, an n-type cathode region 2 with a surface concentration of approximately 1×10¹⁹ cm⁻³ and a diffusion depth of approximately 7 μm is selectively formed as a high-concentration conductive region. The surface of the n-type cathode region 2 contacts a cathode electrode 4, which serves as a metal electrode. The cathode electrode 4 extends to an outer side from an outer peripheral end of the n-type cathode region 2 for approximately 10 μm while sandwiching an insulating film 8 with the n-type cathode region 2.

Additionally, in the diode 20g according to Embodiment 8, unlike in the diodes of Working Example 1 described above, an n-type buffer region 17a with a surface concentration of approximately 5×10¹⁵ cm⁻³, a diffusion depth of approximately 5 μm, and a width of 15 μm is formed so as to contact and surround the outer periphery of the n-type cathode region 2. Further, an edge termination area 11 is formed so as to be spaced apart from and surround the n-type buffer region 17a. Then, a high-concentration p-type isolation region 6 is formed so as to surround the edge termination area 11 and extend from one principal surface of the n-type semiconductor substrate 1 to the other principal surface. Formed on the surface within the edge termination area 11 are: a plurality of p-type field limiting rings (p-type FLRs 7) with a surface concentration of approximately 5×10¹⁸ cm⁻³ and a diffusion depth of approximately 7 μm; and field plates (FPs 9), which are connected to the surfaces of the p-type FLRs 7. The plurality of p-type FLRs 7 are arranged such that the gaps between the p-type FLRs 7 increase from the outer peripheral side of the element to the inner peripheral side. In addition, on the other principal surface (reverse surface) of the n-type semiconductor substrate 1, a p-type anode layer 3 with a surface concentration of approximately 1×10¹⁷ cm⁻³ and a diffusion depth of approximately 1 μm is formed. An anode electrode 5 contacts the p-type anode layer 3 over the entire surface.

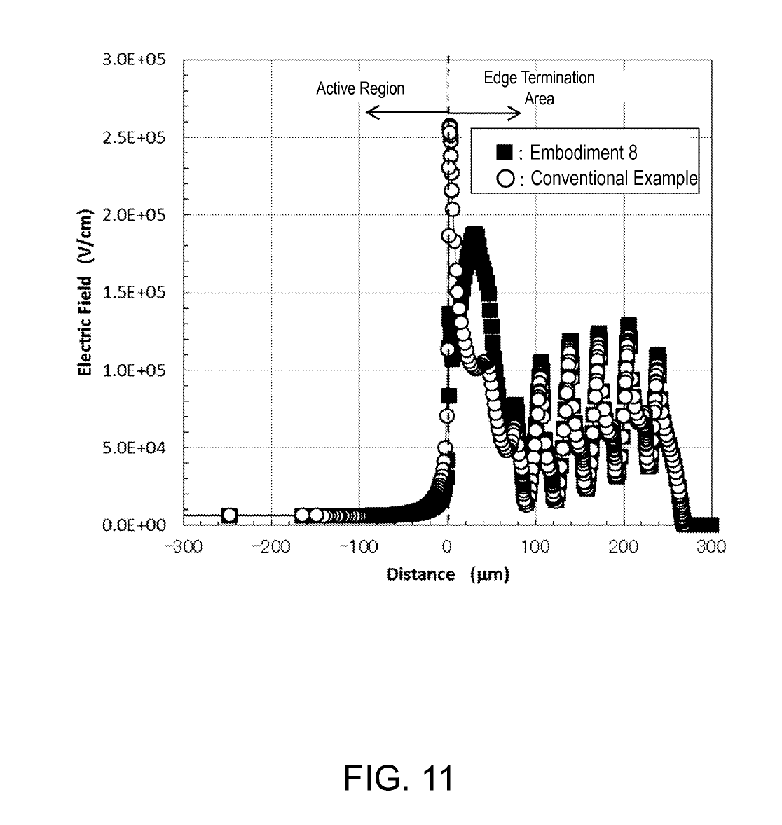

FIG. 11 shows a distribution of the electric field strength of the diode 20g according to Embodiment 8 when a reverse voltage is applied, in comparison to a distribution of the electric field strength of the conventional diode 100 (FIG. 16), in which the n-type buffer region 17a is not formed. FIG. 11 is a distribution of the electric field strength of a cross section along the line A1-A2 in FIG. 10 for a distance of 300 μm from the center, or the boundary between the active region 10 and the edge termination area 11, to the central and outer peripheral sides. It is clear from a comparison with the conventional diode 100 (FIG. 16) in FIG. 11 that the diode 20g according to Embodiment 8 has a lower electric field strength at the outer peripheral end of the cathode region 2 (boundary between the active region 10 and the edge termination area 11). This shows that the diode 20g is able to reduce electric field strength at the outer peripheral end of the cathode region 2 by forming the n-type buffer region 17a. Reduction in electric field strength can prevent a decrease in the breakdown voltage, and is therefore preferable. Additionally, reduction in electric field strength is also preferable for improving reverse recovery resistance and lowering switching loss.

If the concentration of impurities in the n-type buffer region 17a is comparable to that of the cathode region 2, the region with a high electric field strength merely moves from the outer peripheral end of the cathode region 2 to the outer peripheral end of the n-type buffer region 17a. It is desirable, therefore, that the impurity concentration of the n-type buffer region 17a be lower than that of the cathode region 2. Additionally, the diffusion of the n-type buffer region 17a in the diode 20g is formed shallower than that of the n-type cathode region 2. It is preferable, however, that the diffusion of the n-type buffer region 17a be deeper than that of the cathode region 2; a deeper diffusion can increase the curvature of the outer peripheral end of the n-type buffer region and further weaken electric field strength, thereby suppressing a reduction in the reverse breakdown voltage.

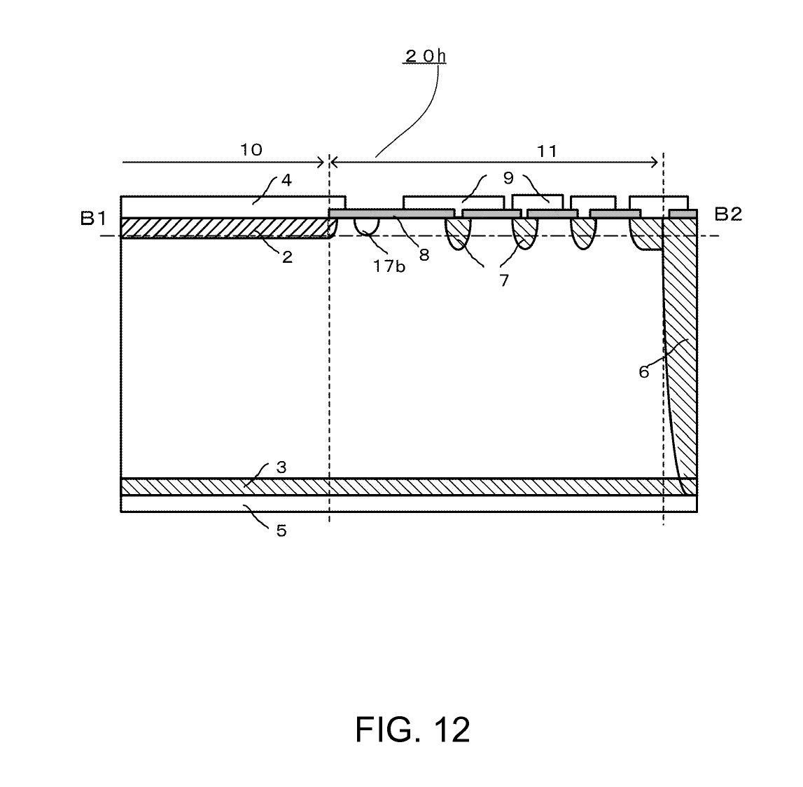

A structure of a diode 20h of Embodiment 9 of a semiconductor device according to one aspect of the present invention will be described with reference to a cross-sectional view of the primary parts in FIG. 12. The diode 20h differs from the diode 20g according to Embodiment 8 in that an n-type buffer region 17b, which is formed so as to contact and surround the outer peripheral end of an n-type cathode region 3, is separated from the n-type cathode region 2 by a gap. Specifically, the n-type buffer region 17b is formed 10 μm wide and 25 μm away from the outer peripheral end of the cathode region 2 toward the outer side.

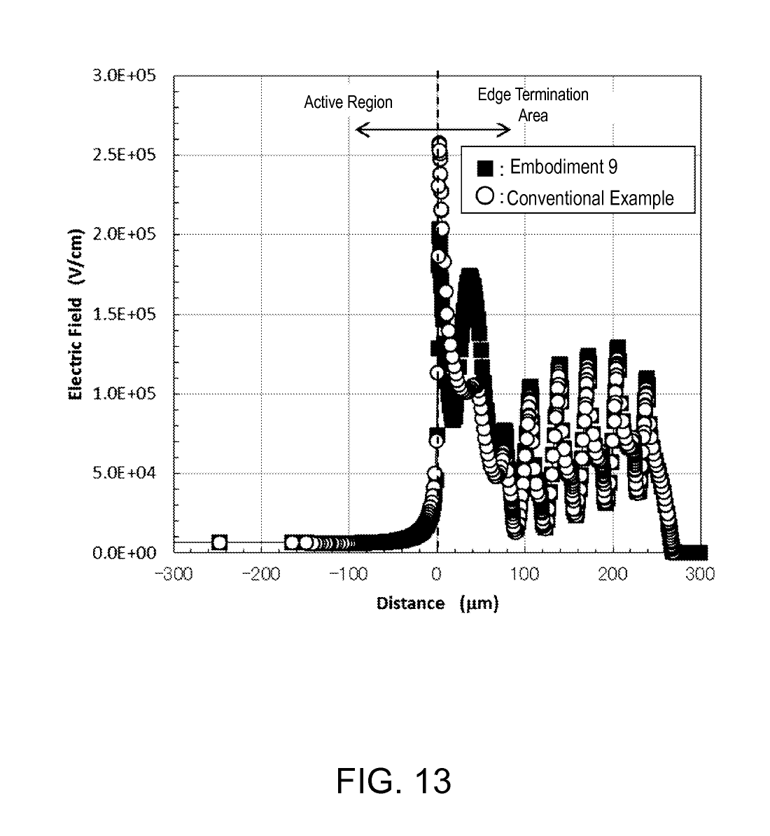

FIG. 13 compares a distribution of the electric field strength of the diode 20h according to Embodiment 9 to a distribution of the electric field strength of the conventional diode 100 (FIG. 16), in which the n-type buffer region 17b is not formed. FIG. 13 is a distribution of the electric field strength of a cross section along the line B1-B2 in FIG. 12 for a distance of 300 μm from the center, or the boundary between the active region 10 and the edge termination area 11, to the central and outer peripheral sides. It is clear from a comparison with the conventional diode 100 (FIG. 16) in FIG. 13 that the diode 20h according to Embodiment 9 has a lower electric field strength at the outer peripheral end of the n-type cathode region 2. This shows that the diode 20h is able to reduce electric field strength at the outer peripheral end of the n-type cathode region 2 even when the n-type buffer region 17b is formed so as to be spaced apart from the n-type cathode region 2. Reduction in electric field strength can prevent a decrease in the breakdown voltage, and is therefore preferable. In addition, reduction in electric field strength is also preferable for improving reverse recovery resistance and lowering switching loss.

Additionally, the diffusion of the n-type buffer region 17b in the diode 20h is also formed shallower than that of the n-type cathode region 2. By forming the diffusion of the n-type buffer region 17b deeper than that of the n-type cathode region 2, it is possible to increase the curvature of the outer peripheral end of the n-type buffer region 17b and further weaken electric field strength. In addition, by forming a plurality of n-type buffer regions 17b so as to be respectively spaced apart from and surround the n-type cathode region 2, it is possible to weaken the electric field strengths of the outer peripheral end of the n-type cathode region 2 and the outer peripheral ends of the n-type buffer regions 17b. Further, connecting a floating electrode (not illustrated) that is not connected to other electrodes to a surface of the n-type buffer region 17b will produce a similar effect.

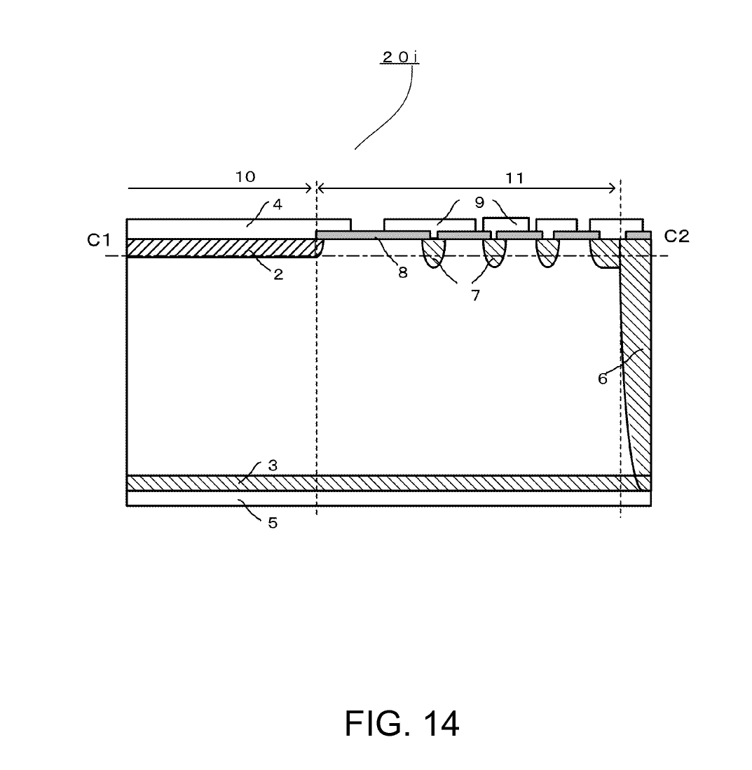

A structure of a diode 20i of Embodiment 10 of a semiconductor device according to one aspect of the present invention will be described with reference to FIG. 14. The diode 20i differs the diode 20h of Embodiment 9 in the following points: the diode 20i does not have an n-type buffer region 17b formed so as to surround an n-type cathode region 2; and a cathode electrode 4, which is connected to the n-type cathode region 2, is extended to the side of an edge termination area 11 while sandwiching an insulating film 8 with the n-type cathode region 2 and functions in a manner similar to an n-type channel stopper region 210 in the conventional diode (FIG. 16). Specifically, the cathode electrode 4 is extended 30 μm to the edge termination area 11 side while sandwiching the insulating film 8 with the n-type cathode region 2.

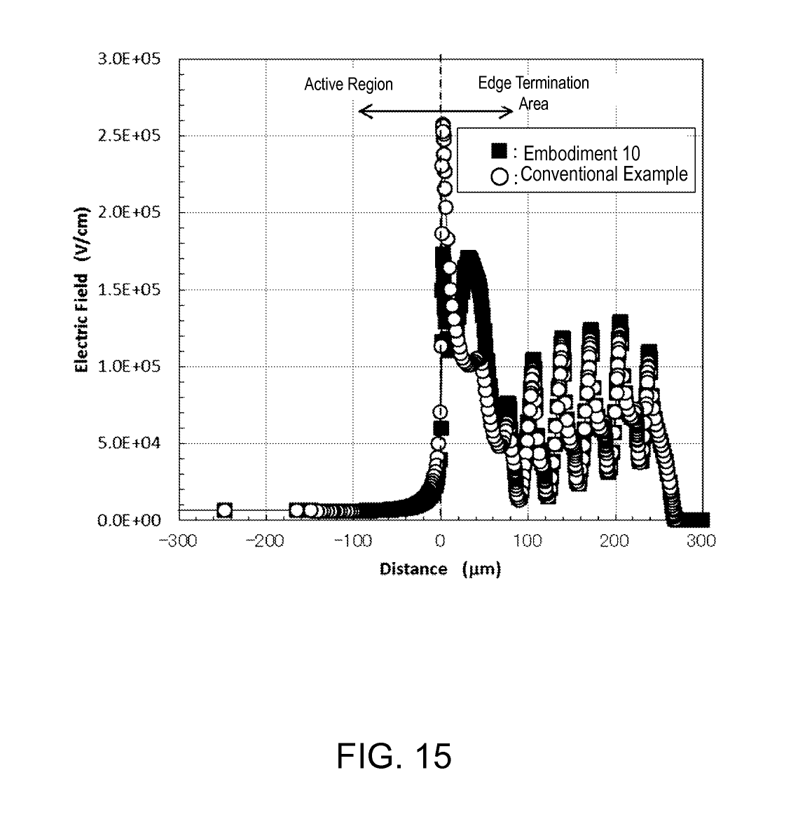

FIG. 15 compares a distribution of the electric field strength of the diode 20i according to Embodiment 10 to a distribution of the electric field strength of the conventional diode (FIG. 16), in which neither the n-type buffer region 17a or the n-type buffer region 17b is formed. FIG. 15 is a distribution of the electric field strength of a cross section along the line C1-C2 in FIG. 14 for a distance of 300 μm from the center, or the boundary between the active region 10 and the edge termination area 11, to the central and outer peripheral sides. It is clear from a comparison with the conventional diode (FIG. 16) in FIG. 15 that the diode 20i according to Embodiment 10 has a lower electric field strength at the outer peripheral end of the n-type cathode region 2 than the conventional diode. This makes it possible to suppress a decrease in breakdown voltage.

Thus, in the diodes according to the aspects of the present invention described above, the n-type cathode region 2 with a high concentration of impurities serves the function of suppressing the depletion layer, which extends from the outer peripheral side of the substrate through the edge termination area toward the active region. Therefore, it is possible to provide a semiconductor device capable of improving the reverse recovery resistance without being constrained by the limitations of conventional measures for improving the reverse recovery resistance while improving the switching loss characteristics by making it easier to obtain a high element breakdown voltage.

It will be apparent to those skilled in the art that various modifications and variations can be made in the present invention without departing from the spirit or scope of the invention. Thus, it is intended that the present invention cover modifications and variations that come within the scope of the appended claims and their equivalents. In particular, it is explicitly contemplated that any part or whole of any two or more of the embodiments and their modifications described above can be combined and regarded within the scope of the present invention.

What is claimed is:

1. A semiconductor device, comprising:
a semiconductor substrate of a first conductivity type, the semiconductor substrate having an edge termination area adjacent to an outermost periphery thereof;
an anode structure provided in a bottom surface of the semiconductor substrate;
a cathode region of the first conductivity type selectively provided in a top surface of said semiconductor substrate at an inner side of the edge termination area;
a cathode electrode on said cathode layer; and
an isolation region of a second conductivity type in the outermost periphery of the semiconductor substrate, the isolation region having a vertically elongated shape such that a bottom of the isolation region is connected to an outermost periphery of said anode structure on the bottom surface of the semiconductor substrate and a top of the isolation region reaches the top surface of the semiconductor substrate.

2. The semiconductor device according to claim 1, wherein said cathode electrode covers, via an insulating film, an outer surface portion of the cathode region and extends so as to cover, via the same insulating film, a portion outside said cathode region.

3. The semiconductor device according to claim 1, wherein said anode structure comprises an anode layer of the second conductivity type provided in the bottom surface of said semiconductor substrate and an anode electrode forming an ohmic contact on said anode layer.

4. The semiconductor device according to claim 1, wherein said anode structure comprises an anode electrode forming a Schottky contact with the bottom surface of said semiconductor substrate of the first conductivity type.

5. The semiconductor device according to claim 1, wherein said edge termination area of the semiconductor substrate has an electric field mitigating structure that comprises: a plurality of field-limiting rings of the second conductivity type provided in the top surface of the semiconductor substrate; and metal field plates respectively in contact with the field-limiting rings.

6. The semiconductor device according to claim 5, wherein gaps between the plurality of field-limiting rings of the second conductivity type gradually widen from said isolation region toward said cathode region.

7. The semiconductor device according to claim 5, wherein said electric field mitigating structure has a reduced surface field (RESURF) region of the second conductivity type contacting said isolation region on the bottom surface of the semiconductor substrate.

8. The semiconductor device according to claim 5, wherein said electric field mitigating structure further includes a ring-shaped buffer region of the first conductivity type in a periphery of said cathode region, said ring-shaped buffer region having a lower concentration of impurities than said cathode region.

9. The semiconductor device according to claim 8, wherein said ring-shaped buffer region of the first conductivity type contacts a peripheral side of said cathode region.

10. The semiconductor device according to claim 8, wherein said ring-shaped buffer region of the first conductivity type is provided so as to be spaced apart from a peripheral side of said cathode region.

11. The semiconductor device according to claim 8, wherein said ring-shaped buffer region of the first conductivity type is electrically connected to an electrode that is set at a floating potential.

12. The semiconductor device according to claim 8, wherein said ring-shaped buffer region of the first conductivity type is formed in a plurality.
